(19) United States
(12) Patent Application Publication
(10) Pub. No.: US 2025/0081542 A1
(43) Pub. Date: Mar. 6, 2025

(54) SEMICONDUCTOR STRUCTURE AND METHOD FOR FORMING THE SAME

(71) Applicant: Winbond Electronics Corp., Taichung City (TW)

(72) Inventors: Yao-Ting TSAI, Kaohsiung City (TW); Po-Yen HSU, Taichung City (TW)

(21) Appl. No.: 18/673,901

(22) Filed: May 24, 2024

(30) Foreign Application Priority Data
Aug. 28, 2023 (TW) 112132268

(51) Int. Cl. H01L 29/423; H01L 21/762; H01L 21/768; H01L 29/66

(52) U.S. Cl. CPC H10D 30/6894; H01L 21/76232; H01L 21/76831; H10D 64/015

(57) ABSTRACT

A method for forming a semiconductor structure is provided. The method includes providing a semiconductor substrate with a tunnel dielectric layer, a conductive layer and a hard mask layer; etching the semiconductor layer, the tunnel dielectric layer, the conductive layer and the hard mask layer to define stack structures and trenches; forming a liner on the sidewalls of the stack structures; forming an isolation structure in the trenches; removing the hard mask layer to form openings exposing the conductive layer; filling the openings with a conductive material to form a floating gate which includes a lower portion covered by the liner and an upper portion not covered by the liner; recessing the isolation structure to expose the sidewalls of the upper portion of the floating gate; forming an inter-gate dielectric (IGD) layer on the isolation structure and the floating gate; and forming a control gate on the IGD layer.

### CROSS REFERENCE TO RELATED APPLICATIONS

This application claims priority of Taiwan Patent Application No. 112132268, filed on Aug. 28, 2023, the entirety of which is incorporated by reference herein.

### BACKGROUND

### Technical Field

The present disclosure relates to a semiconductor structure and a method for forming the same, and, in particular, to a flash memory structure and a method of forming the same.

### Description of the Related Art

Non-volatile memory includes a floating gate for capturing and storing electrons, a control gate for controlling potential, and a tunnel oxide layer (TOX layer) that provides an electron tunneling channel effect. As the scaling down of semiconductor devices has become a trend, the size of non-volatile memory continues to reduce to increase integration and improve performance. However, this continuous reduction in size makes it easy for defects to arise in the process, such as corner thinning of the tunnel oxide layer, which can have an adverse effect on memory performance. Therefore, there are still some issues to be addressed in the existing semiconductor structure and the manufacturing method thereof.

### SUMMARY

An embodiment of the present disclosure provides a method of forming a semiconductor structure. The method includes providing a semiconductor substrate having a tunnel dielectric layer, a conductive layer, and a mask layer sequentially formed thereon; etching the semiconductor substrate, the tunnel dielectric layer, the conductive layer, and the mask layer to define a plurality of stack structures and a plurality of trenches formed between the stack structures; forming a liner on sidewalls of the stack structures; forming an isolation structure in the trenches; removing the mask layer to form an opening exposing the conductive layer; filling the opening with a conductive material to form a floating gate composed of the conductive material and the conductive layer, wherein the floating gate comprises a lower portion covered by the liner and an upper portion not covered by the liner; recessing the isolation structure to expose the sidewalls of the upper portion of the floating gate, wherein the tunnel dielectric layer is protected by the liner during the recessing; forming an inter-gate dielectric layer on the isolation structure and the floating gate; and forming a control gate on the inter-gate dielectric layer.

An embodiment of the present disclosure provides a semiconductor structure, including: a semiconductor substrate; a plurality of tunnel dielectric layers disposed on the semiconductor substrate; a plurality of floating gates disposed on the tunnel dielectric layers, wherein each of the floating gates including: an upper portion and a lower portion; a plurality of liners covering sidewalls of the lower portion of the floating gates; an isolation structure disposed between the floating gates; an inter-gate dielectric layer disposed on the floating gates and the isolation structure; and a control gate disposed on the inter-gate dielectric layer.

### BRIEF DESCRIPTION OF THE DRAWINGS

FIGS. 1-8, 9A illustrate cross-sectional views in intermediate stages of forming a semiconductor structure, in accordance with some embodiments of the present disclosure.

FIG. 9B illustrates a top view taken along line A-A′ of FIG. 9A, in accordance with some embodiments of the present disclosure.

FIGS. 10-14 are cross-sectional views in intermediate stages of forming another semiconductor structure, in accordance with some embodiments of the present disclosure.

### DETAILED DESCRIPTION OF THE INVENTION

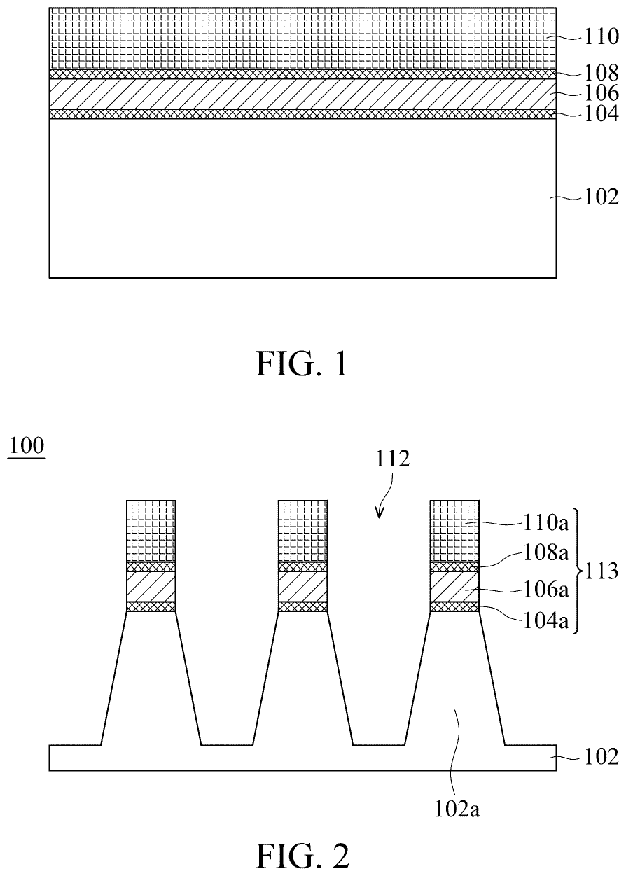

FIGS. 1-9A illustrate cross-sectional views in intermediate stages of forming semiconductor structure 100, in accordance with some embodiments of the present disclosure. First, referring to FIG. 1, a semiconductor substrate 102 with a tunnel dielectric layer 104, a conductive layer 106, a dielectric layer 108, and a mask layer 110 sequentially formed thereon is provided.

The material of tunnel dielectric layer 104 may include oxide (e.g., silicon oxide (SiOx)), and the tunnel dielectric layer 104 may be formed of thermal oxidation, physical vapor deposition (PVD), chemical vapor deposition (CVD), low pressure chemical vapor deposition (LPCVD), plasma enhanced CVD (PECVD), or other suitable process. After forming the tunnel dielectric layer 104, the conductive layer 106 is deposited over the tunnel dielectric layer 104. The material of the conductive layer 106 may be, for example, undoped polycrystalline silicon, doped polycrystalline silicon, amorphous silicon, metal, polycide, the like, or combinations thereof. For example, in some embodiments, the material of the conductive layer 106 may be doped polycrystalline silicon.

Still referring to FIG. 1, the dielectric layer 108 and the hard mask layer 110 are formed over the conductive layer 106. In some embodiments, the material of the dielectric layer 108 may be silicon oxide, and the dielectric layer 108 may be formed by atomic layer deposition (ALD). the material of the hard mask layer 110 may be silicon nitride.

Referring to FIG. 2, the hard mask layer 110, the dielectric layer 108, conductive layer 106, the tunnel dielectric layer 104, and the semiconductor substrate 102 are sequentially etched to form stack structures 113 and trenches 112 between the stack structures 113. Each of the stack structures 113 is located over the substrate protruding portion 102a between the trenches 112, and each of the stack structures 113 includes portions of the etched tunnel dielectric layer 104a, the conductive layer 106a, the dielectric layer 108a, and the hard mask 110a.

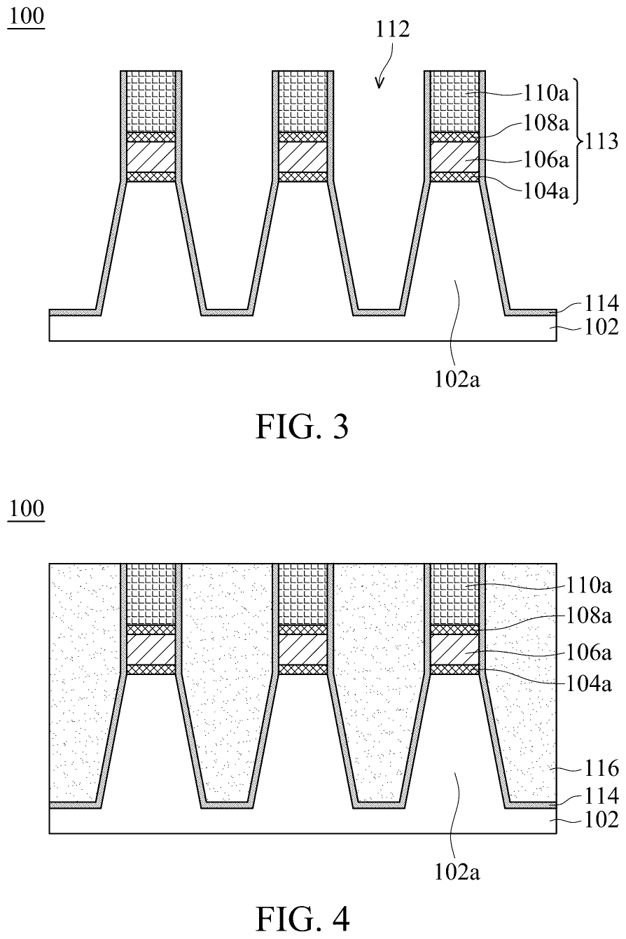

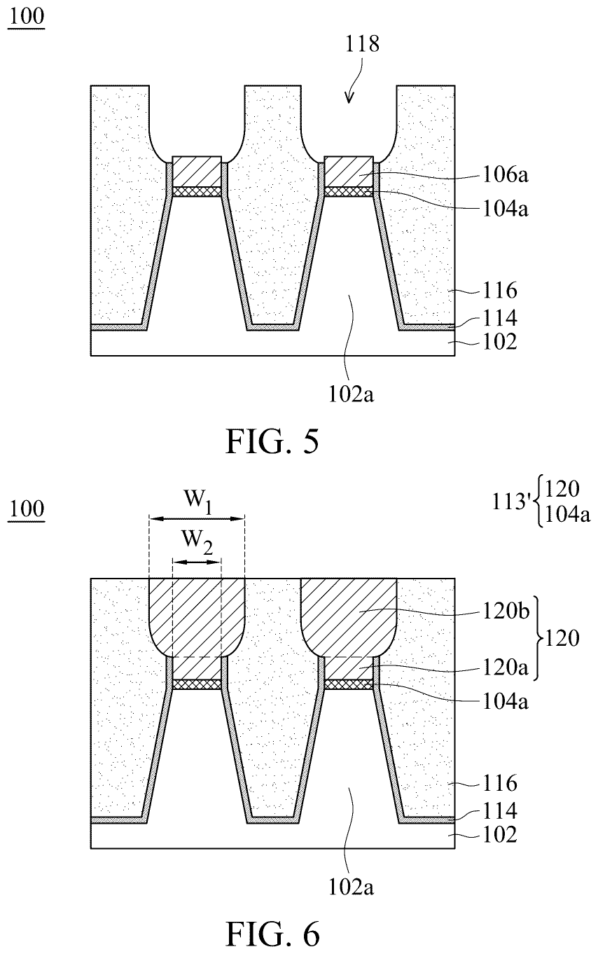

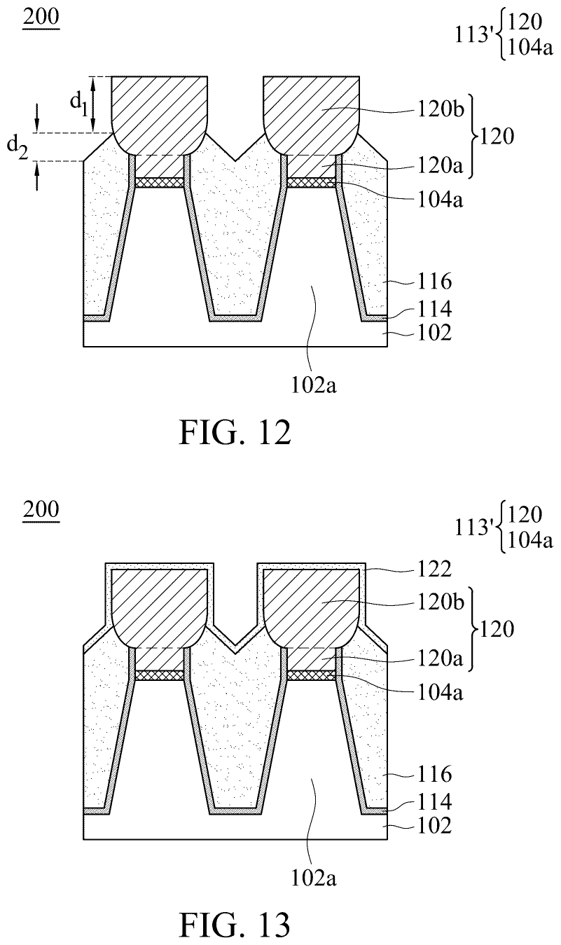

Referring to FIG. 3, a liner 114 is formed on the sidewalls of the stack structures 113. For example, the liner 114 is further formed on the sidewalls of the substrate protruding portion 102a and the stack structures 113 shown in FIG. 2. During the subsequent processes of recessing the openings 118 (FIG. 5) and the isolation structure 116 (FIG. 12), the liner 114 can protect the underlying tunnel dielectric layer 104a, the conductive layer 106a, or the floating gate 120. In some embodiments, the liner 114 may be a dense oxide layer formed by in-situ steam generation (ISSG), and the material thereof may be, for example, silicon oxide. In some embodiments, the entirety of the sidewalls of the conductive layer 106a is surrounded by the liner 114.

Referring to FIG. 4, a dielectric material is filled into the trenches 112 by a deposition process, for example, spin on glass (SOG), CVD, high density plasma CVD (HDP-CVD), ALD, other suitable process, or combinations thereof (e.g., combining HDP-CVD and SOG), followed by a planarization process (e.g., chemical mechanical planarization (CMP)) to remove excess dielectric material, thereby forming an isolation structure 116 with its top surface level with the top surfaces of the stack structures 113. In some embodiments, the materials of the isolation structure 116 and the liner 114 may be the same. However, it should be noted that based on the differences between the processes of forming the isolation structure 116 and the liner 114, despite the same material may be used, an interface and/or property difference may be existed microscopically between the liner 114 and the isolation structure 116. For example, in some embodiments, both of the materials of the liner 114 and the isolation structure 116 are silicon oxide; however, the liner 114 may be formed by in-situ steam generation (ISSG), whereas the isolation structure 116 may be formed by HDP-CVD or SOG process. Accordingly, the liner 114 may have an oxidized structure denser than the isolation structure 116, and the etch rates of the both may be different. Therefore, the liner 114 can provide sufficient protection for the underlying tunnel dielectric layer 104a and the conductive layer 106a during the subsequent etching process.

Still referring to FIG. 5, an etching process may be performed to remove the hard masks 110a and the dielectric layers 108a to form openings 118 exposing the underlying conductive layers 106a. During the etching process, the liner 114 can protect the tunnel dielectric layer 104a and the conductive layer 106a covered by the liner 114, and reduce the corner thinning caused by the damages of the tunnel dielectric layer 104a. In some embodiments, the etching process may also remove portions of the liner 114 and the isolation structure 116. Therefore, the width of the opening 118 may be greater than the width of the original hard mask 110a, and portions of the sidewalls of the conductive layer 106a may be exposed.

Referring to FIG. 6, the openings 118 are filled with the conductive material, and then subjected to a planarization process to level the top surfaces of the filled conductive material and the isolation structure 116, thereby obtaining a floating gate 120 composed of the conductive material and the conductive layer 106a. The floating gate 120 includes a lower portion 120a with sidewalls covered by the liner 114, and an upper portion 120b with sidewalls not covered by the liner 114. In the following context, the stack structure including the floating gate 120 and the tunnel dielectric layer 104a may be represented by the stack structure 113′. The openings 118 may be filled by any suitable method to form the floating gate 120, for example, PVD, CVD, ALD, LPCVD, or other suitable process. In some embodiments, the profile of the sidewall of the upper portion 120b is a curve, and the profile of the sidewall of the lower portion 120a is a straight line. The top surface of the upper portion 120b has a first width W₁ and the top surface of the lower portion 120a has a second width W₂, wherein the first width W₁ is greater than the second width W₂. The cross-section of the upper portion 120b of the floating gate 120 may be bowl-shaped. In some embodiments, the conductive material may be the same as the material of the conductive layer 106a. The conductive material may be different from the material of the conductive layer 106a. An ion implantation process may be further included in the formation of the floating gate 120. For example, the floating gate 120 may be formed by a deposition process such as LPCVD to deposit a polycrystalline silicon layer using silane as a source gas, followed by dopant implantation.

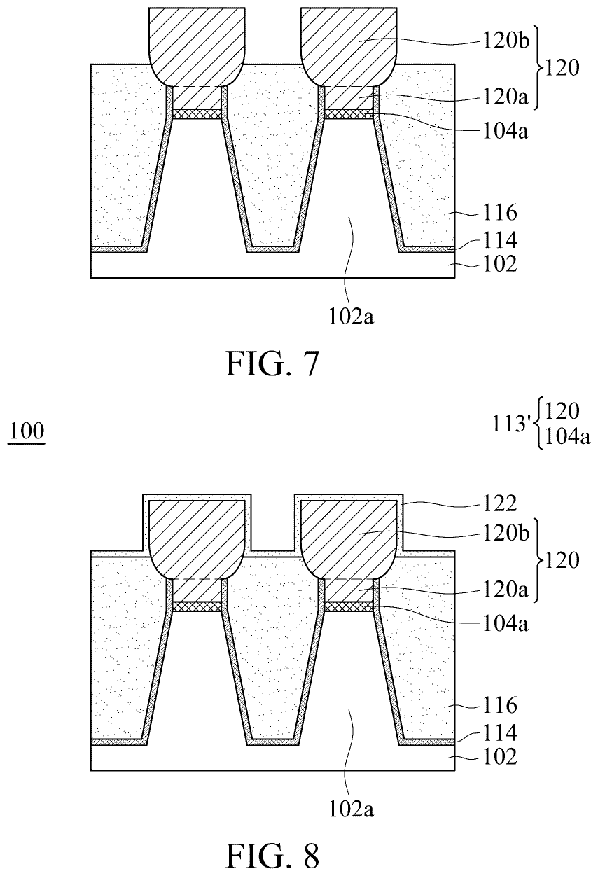

Referring to FIG. 7, the isolation structure 116 is recessed to expose portions of the sidewalls of the floating gate 120. In some embodiments, the top surface of the recessed isolation structure 116 may be located between the top surface and the bottom surface of the upper portion 120b of the floating gate 120. That is, the etching process exposes portions of the sidewalls of the upper portion 120b of the floating gate 120, but does not expose the sidewalls of the lower portion 120a of the floating gate 120 and/or the liner 114. In the embodiment shown in FIG. 7, the recessed isolation structure 116 has a flat top surface.

Referring to FIG. 8, an inter-gate dielectric layer 122 is conformally formed over the semiconductor structure 100 to cover the top surface and sidewalls of the floating gate 120 and the top surface of the isolation structure 116. In some embodiments, the inter-gate dielectric layer 122 may be a single layer structure or a multilayer structure, and the material of the inter-gate dielectric layer 122 may be oxide, nitride, or combinations thereof. For example, the inter-gate dielectric layer 122 may have an oxide/nitride/oxide (ONO) structure. The inter-gate dielectric layer 122 may not directly contact the lower portion 120a of the floating gate 120 and the liner 114.

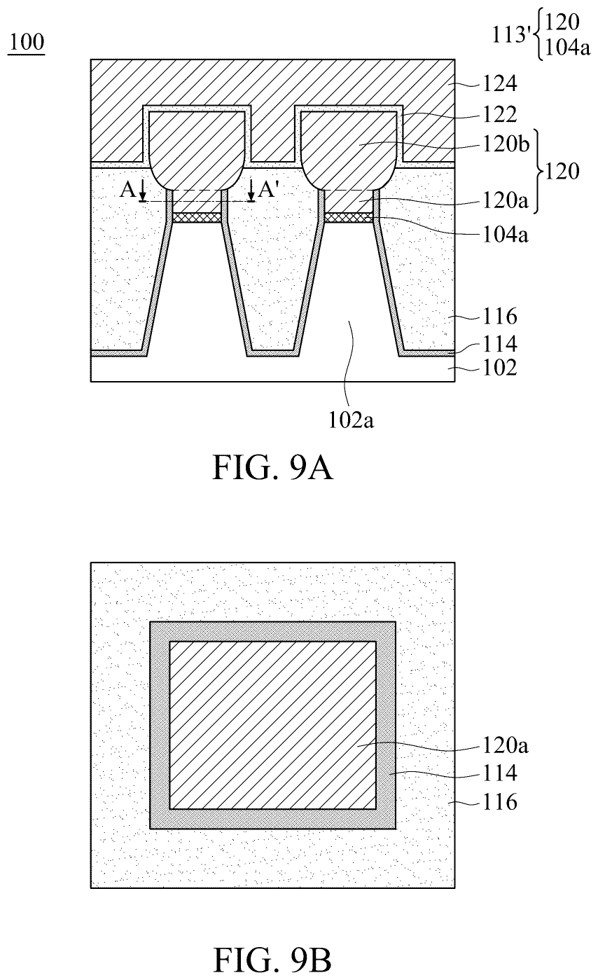

Referring to FIG. 9A, a control gate 124 is formed on the inter-gate dielectric layer 122, thereby obtaining the semiconductor structure 100. In some embodiments, the control gate 124 may be a single layer or multilayer structure, and the material of the control gate 124 may include: polycrystalline silicon, metal, polyicide, similar conductive material, or combinations thereof. After forming the control gate 124, other conventional processes may be continued to complete a semiconductor device such as a memory, which are omitted herein for the sake of brevity.

FIG. 9B illustrates a top view of the semiconductor 100 taken along the line A-A′ of FIG. 9A, in accordance with some embodiments of the resent disclosure. As shown in FIGS. 9A and 9B, in some embodiments, the entirety of the sidewalls of the tunnel dielectric layer 104a and the lower portion 120a of the floating gate 120 of the semiconductor structure 100 are surrounded by the liner 114, thereby providing a protection for the lower portion 120a of the floating gate 120 and the tunnel electric layer 104a during the etching process, and reducing the corner thinning caused by the damages of the tunnel dielectric layer 104a.

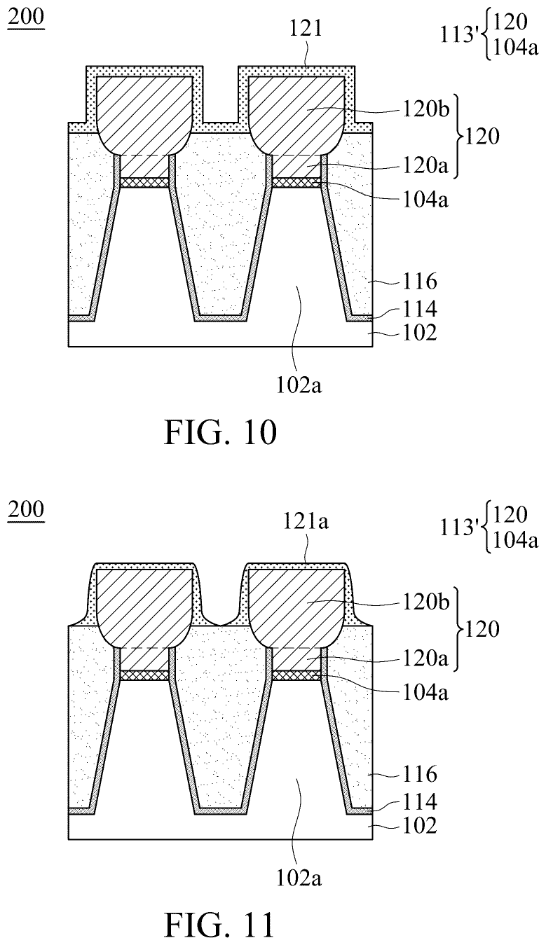

FIGS. 10-14 illustrate cross-sectional views in stages of forming the semiconductor structure 200, in accordance with another embodiment of the present disclosure. Refer to FIG. 10, which continues the process of recessing the isolation structure 116 in FIG. 7 (hereinafter, “the first recess process”). In this embodiment, a second recess process is performed on the isolation structure 116 to form a concave top surface of the isolation structure 116. After completing the first recess process of FIG. 7, a dielectric material layer 121 may be conformally formed over the semiconductor structure 200. That is, the dielectric material layer 121 may cover the top surface and the exposed sidewalls of the floating gate 120 and the top surface of the isolation structure along the contour of the floating gate 120 and the isolation structure 116. The dielectric material layer 121 may be formed by processes such as CVD or ALD. The dielectric material layer 114 may be an oxide, for example, an oxide formed by using tetraethoxysilane (TEOS) as a precursor.

Referring to FIG. 11, an anisotropic etching process may be performed on the semiconductor structure 200 to remove portions of the dielectric material layer 121, thereby forming a plurality of sacrificial spacers 121a on the opposite sidewalls of the floating gate 120. The sacrificial spacers 121a may be formed by any suitable process, for example, reactive ion etching (RIE). The sacrificial spacers 121a are configured to cover the top surface and portions of sidewalls of the floating gate 120 to protect the floating gate 120 from over-etching during the subsequent etching of the isolation structure 116. In some embodiments, the sacrificial spacers 121a only cover the top surface and sidewalls of the floating gate 120, but they do not cover the top surface of the isolation structure 116 (not shown).

Referring to FIG. 12, a second recess process is performed on the semiconductor structure 200 to remove the sacrificial spacers 121a and further recess the isolation structure 116. In some embodiments, the second recess process may be the same etching process as the first recess process. The first recess process recesses the top surface of the isolation structure 116 from a horizontal plane level with the top surface of the floating gate 120 down to a first depth d₁, whereas the second recess process further recesses portions of the top surface of the isolation structure 116 from a horizontal plane level with the recessed top surface of the isolation structure 116 down to a second depth d₂. In particular, since the central line portion of the isolation structure 116 is not covered by the sacrificial spacers 121a or is covered by a thinner thickness, it will be etched deeper. On the contrary, the portion of the isolation structure 116 away from the centerline is covered by the thicker sacrificial spacer 121a and therefore will be etched shallower. Accordingly, the isolation structure 116 may have a concave top surface directed toward the semiconductor substrate 102. Compared to the embodiments of FIG. 8-9A, the isolation structure 116 of this embodiment is recessed to a deeper depth. Therefore, the coupling effect between the floating gates 120 may be reduced, thereby increasing the reliability of the device. It should be noted that the second recess process still protect the sidewalls of the lower portion 120a of the floating gate 120 and/or the sidewalls of the tunnel dielectric layer 104a from exposure, which helps maintain the performance of the device. Therefore, during the second recess process, the liner 114 may protect the lower portion 120a of the floating gate 120 and the tunnel dielectric layer 104a. The first recess process and the second recess process may be the same etching process, such as reactive ion etching. The horizontal plane of the lower end of the first depth d₁ is located between the top surface and the bottom surface of the upper portion 120b of the floating gate 120, whereas the horizontal plane of the lower end of the second depth d₂ is located between the top surface and the bottom surface of the lower portion 120a of the floating gate 120. In some embodiments, after the second recess process, the first width w₁ of the upper portion 120b of the floating gate 120 may be about 65 nm to about 70 nm.

Referring to FIG. 13, the inter-gate dielectric layer 122 is conformally formed over the semiconductor structure 200 to cover the top surface and the sidewalls of the floating gate 120 and the top surface of the isolation structure 116. The forming method and related properties of the inter-gate dielectric layer 122 are similar to those described in FIG. 8, and will not be repeated herein for brevity.

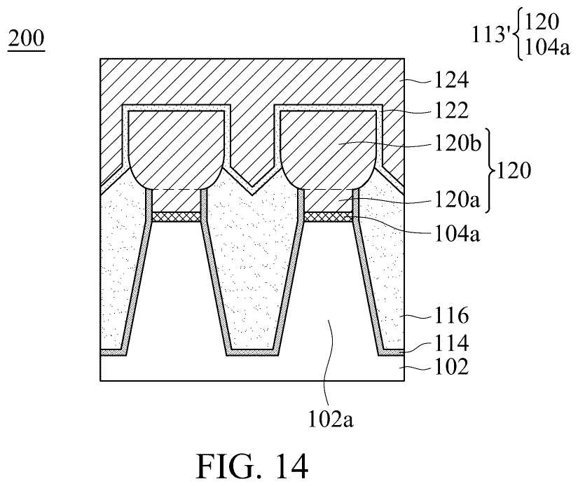

Finally, referring to FIG. 14, the control gate 124 is formed over the inter-gate dielectric layer 122, thereby obtaining the semiconductor structure 200. The forming method and related properties of the control gate 124 are similar to those described in FIG. 9A, and will not be repeated herein for brevity.

Various embodiments described in the present disclosure provide several advantages in the technical field. It should be appreciated that not all advantages of the present disclosure have been discussed herein, and not all embodiments are necessary to have the specific advantages, and different advantages may be provided by other embodiments. To sum up, through forming a liner covering the sidewalls of the lower portion of the floating gate, embodiments of the present disclosure can protect the floating gate and/or the tunnel dielectric layer during the etching process, and reduce the corner thinning caused by the damages of the tunnel dielectric layer during the etching process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
providing a semiconductor substrate having a tunnel dielectric layer, a conductive layer, and a mask layer sequentially formed thereon;
etching the semiconductor substrate, the tunnel dielectric layer, the conductive layer, and the mask layer to define a plurality of stack structures and a plurality of trenches formed between the stack structures;
forming a liner on sidewalls of the stack structures;
forming an isolation structure in the trenches;
removing the mask layer to form an opening exposing the conductive layer;
filling the opening with a conductive material to form a floating gate composed of the conductive material and the conductive layer, wherein the floating gate comprises a lower portion covered by the liner and an upper portion not covered by the liner;
recessing the isolation structure to expose sidewalls of the upper portion of the floating gate, wherein the tunnel dielectric layer is protected by the liner during the recessing;
forming an inter-gate dielectric layer on the isolation structure and the floating gate; and
forming a control gate on the inter-gate dielectric layer.

2. The method as claimed in claim 1, wherein the liner surrounds the entirety of the sidewalls of the lower portion of the floating gate.

3. The method as claimed in claim 1, wherein the liner is formed by in-situ steam generation (ISSG).

4. The method as claimed in claim 1, wherein the recessing of the isolation structure does not expose the lower portion of the floating gate and the liner.

5. The method as claimed in claim 1, wherein the isolation structure has a flat top surface after the recessing.

6. The method as claimed in claim 1, wherein the liner and the isolation structure are respectively formed of a material comprising oxide.

7. The method as claimed in claim 1, wherein a cross-section of the upper portion of the floating gate is bowl-shaped.

8. The method as claimed in claim 1, wherein before the recessing of the isolation structure, the method further comprises:
forming a plurality of sacrificial spacers on sidewalls of the upper portion of the floating gate; and
the recessing of the isolation structure further comprising: removing the sacrificial spacers and forming a concave top surface between the sacrificial spacers.

9. The method as claimed in claim 8, wherein the concave top surface is concave toward the semiconductor substrate.

10. A semiconductor structure, comprising:
a semiconductor substrate;
a plurality of tunnel dielectric layers disposed on the semiconductor substrate;
a plurality of floating gates disposed on the tunnel dielectric layers, wherein each of the floating gates comprises: an upper portion and a lower portion;
a plurality of liners covering sidewalls of the lower portion of the floating gates;
an isolation structure disposed between the floating gates;
an inter-gate dielectric layer disposed on the floating gates and the isolation structure; and
a control gate disposed on the inter-gate dielectric layer.

11. The semiconductor structure as claimed in claim 10, wherein a top surface of the isolation structure is between a top surface and a bottom surface of the upper portion of the floating gate.

12. The semiconductor structure as claimed in claim 10, wherein a thickness of the liner is 1 nm to 20 nm.

13. The semiconductor structure as claimed in claim 10, wherein a cross-section of the upper portion of the floating gate is bowl-shaped.

14. The semiconductor structure as claimed in claim 10, wherein a profile of sidewalls of the upper portion of the floating gate is a curve.

15. The semiconductor structure as claimed in claim 14, wherein a profile of the sidewall of the lower portion of the floating gate is a straight line.

16. The semiconductor structure as claimed in claim 10, wherein the isolation structure has a flat top surface.

17. The semiconductor structure as claimed in claim 10, wherein the isolation structure has a concave top surface that is concave toward the semiconductor substrate.

18. The semiconductor structure as claimed in claim 17, wherein the inter-gate dielectric layer is not directly contact with the liner and the lower portion of the floating gate.
